(19) United States
(12) Patent Application Publication
(10) Pub. No.: US 2017/0075103 A1
(43) Pub. Date: Mar. 16, 2017

(54) ELECTROMECHANICAL SYSTEMS DEVICE WITH SEGMENTED ELECTRODES AND THIN FILM TRANSISTORS FOR INCREASING STABLE RANGE

(71) Applicant: QUALCOMM MEMS Technologies, Inc., San Diego, CA (US)

(72) Inventors: Bing Wen, Poway, CA (US); Edward Keat Leam Chan, San Diego, CA (US); Tallis Young Chang, San Diego, CA (US)

(21) Appl. No.: 14/852,211

(22) Filed: Sep. 11, 2015

(51) Int. Cl. G02B 26/00; H01L 27/12; G09G 3/34

(52) U.S. Cl. CPC G02B 26/001; G09G 3/3466; H01L 27/124; H01L 27/1259; H01L 27/1248; G09G 2300/0421

(57) ABSTRACT

This disclosure provides systems, methods, and apparatus for electromechanical systems (EMS) devices with a plurality of electrically isolated electrode segments each connected to a distinct thin film transistor (TFT), where a plurality of TFTs drive the EMS device by applying a common voltage to the plurality of electrode segments. The plurality of TFTs can be configured to allow each electrode segment to have its own voltage during actuation. The EMS device can include a substrate, a stationary electrode over the substrate, and a movable electrode over the stationary electrode with a gap defined between the stationary electrode and the movable electrode. At least one of the stationary electrode and the movable electrode includes the plurality of electrode segments. The plurality of TFTs and the plurality of electrode segments can increase the stable range of the EMS device.

### TECHNICAL FIELD

This disclosure relates to an electromechanical systems device, and more particularly to an electromechanical systems device including two or more electrically isolated electrode segments each connected to a distinct thin film transistor.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

Many EMS and MEMS devices apply a voltage to generate an electrostatic attraction between two electrodes to cause one electrode to move in relation to the other electrode. The positions of one or both of the electrodes can become unstable as the electrostatic force between the electrodes increases quadratically with decreasing distance between the electrodes. For example, after a movable electrode travels a certain distance, the movable electrode can quickly travel the remaining separation distance, which is a phenomenon referred to as “snap-through.” In addition, tilt can occur if the movable electrode has any asymmetry or experiences any degree of asymmetric perturbation, and charge can build up in the area of the tilt that can serve as a positively reinforcing mechanism, which results in tilt instability. Beyond a certain critical travel range, tilting can become unstable and one side or corner of the EMS or MEMS device can snap down.

### SUMMARY

The systems, methods, and devices of this disclosure each have several innovative aspects, no single one of which is solely responsible for the desirable attributes disclosed herein.

One innovative aspect of the subject matter described in this disclosure can be implemented in an EMS device. The EMS device includes a substrate, a stationary electrode over the substrate, a movable electrode over the stationary electrode with a gap between the movable electrode and the stationary electrode, and a plurality of thin film transistors (TFTs). At least one of the stationary electrode and the movable electrode includes a plurality of electrically isolated electrode segments. Each of the TFTs are connected to and correspond to a distinct one of the plurality of electrode segments, the plurality of TFTs configured to drive the movable electrode to two or more positions across the gap by a common voltage.

In some implementations, the plurality of electrically isolated electrode segments include four or more electrically isolated electrode segments. In some implementations, the plurality of TFTs are configured to maintain a fixed charge in the plurality of electrically isolated electrode segments when the movable electrode is driven across the gap. In some implementations, the EMS device further includes a gate line electrically coupled to the plurality of TFTs, wherein each of the plurality of TFTs share the gate line, and a data line electrically coupled to the plurality of TFTs, wherein each of the plurality of TFTs share the data line. In some implementations, the EMS device further includes a plurality of hinges connected to the movable electrode, wherein at least one of the hinges includes the gate line and at least one of the hinges includes the data line.

Another innovative aspect of the subject matter described in this disclosure can be implemented in an EMS device. The EMS device includes a substrate, a stationary electrode over the substrate, a movable electrode over the stationary electrode with a gap between the movable electrode and the stationary electrode, and means for maintaining a fixed charge in the electrically isolating means when the movable electrode is driven across the gap. At least one of the stationary electrode and the movable electrode includes means for electrically isolating into electrode segments, and the means for maintaining the fixed charge are connected to the electrically isolating means and configured to drive the movable electrode across the gap by a common voltage.

In some implementations, the maintaining the fixed charge means include a plurality of thin film transistors (TFTs), each of the plurality of TFTs connected to and corresponding to a distinct one of the electrode segments. In some implementations, the EMS device further includes a gate line electrically coupled to the plurality of TFTs, wherein each of the plurality of TFTs share the gate line, and a data line electrically coupled to the plurality of TFTs, wherein each of the plurality of TFTs share the data line. In some implementations, the electrically isolating means includes four or more electrically isolated electrode segments each separated by dielectric material.

Another innovative aspect of the subject matter described in this disclosure can be implemented in a method of manufacturing an EMS device. The method includes providing a first substrate, forming a plurality of TFTs on the first substrate, forming a plurality of electrically isolated electrode segments over the TFTs where each of the TFTs connect to and correspond to a distinct one of the plurality of electrode segments, and forming a movable electrode over the electrode segments and separated by a gap therebetween. The movable electrode is supported by a plurality of hinges connected to the movable electrode, where the plurality of TFTs are configured to drive the movable electrode to two or more positions across the gap by a common voltage.

In some implementations, the method further includes forming a dielectric layer between the TFTs and the electrode segments, the dielectric layer electrically isolating the electrode segments from one another, and forming a plurality of vias extending through the dielectric layer to connect the plurality of TFTs to the plurality of electrode segments. IN some implementations, the plurality of electrically isolated electrode segments include four or more electrically isolated electrode segments. In some implementations, the method further includes providing a second substrate opposite the first substrate, wherein the plurality of hinges are formed on the second substrate for supporting the movable electrode.

Another innovative aspect of the subject matter described in this disclosure can be implemented in a method of manufacturing an EMS device. The method includes providing a substrate, forming a stationary electrode on the substrate, forming a plurality of electrically isolated electrode segments in a movable layer where the movable layer and the stationary electrode are separated by a gap therebetween, and forming a plurality of TFTs over the electrode segments in the movable layer. Each of the TFTs are connected to and correspond to a distinct one of the plurality of electrode segments, where the movable layer is supported by a plurality of hinges connected to the movable layer, and where the plurality of TFTs are configured to drive the movable layer to two or more positions across the gap by a common voltage.

In some implementations, the method further includes forming the plurality of hinges on the substrate for supporting the movable layer, where at least one of the hinges includes a gate line and wherein at least one of the hinges includes a data line. In some implementations, the method further includes forming a dielectric layer between the TFTs and the electrode segments, the dielectric layer electrically isolating the electrode segments from one another, and forming a plurality of vias extending through the dielectric layer to connect the plurality of TFTs to the plurality of electrode segments.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays (LCDs), organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIGS. 3A-3E are cross-sectional illustrations of varying implementations of IMOD display elements.

FIG. 4 shows a cross-sectional schematic diagram of an example two-terminal EMS device with unsegmented electrodes.

FIG. 5 shows a cross-sectional schematic diagram of an example two-terminal EMS device with a movable electrode over a stationary electrode, where the stationary electrode has two or more electrically isolated electrode segments.

FIG. 6A shows a perspective schematic diagram of an example two-terminal EMS device with an electrode segmented into four quadrants.

FIG. 6B shows a schematic top view of a movable electrode with four hinges connected at the edges of the movable electrode for the example two-terminal EMS device of FIG. 6A.

FIG. 6C shows a schematic top view of a movable electrode with four hinges connected at the corners of the movable electrode for the example two-terminal EMS device of FIG. 6A.

FIG. 7 shows a cross-sectional schematic diagram of an example EMS device with a stationary electrode having two or more electrically isolated electrode segments each connected to a TFT.

FIG. 8 shows a cross-sectional schematic diagram of an example EMS device with a segmented stationary electrode formed on a first substrate and an unsegmented movable electrode formed on a second substrate.

FIG. 9A shows a cross-sectional schematic side view of an example EMS device with a movable electrode having two or more electrically isolated electrode segments each connected to a TFT.

FIG. 9B shows a cross-sectional schematic top view of a plurality of example EMS devices from FIG. 9A with shared gate and data lines.

FIG. 10A shows a schematic diagram of an example electrode separated into halves.

FIG. 10B shows a schematic diagram of an example electrode separated into thirds.

FIG. 10C shows a schematic diagram of an example electrode separated into fourths.

FIG. 11 shows a flow diagram illustrating an example process for manufacturing an EMS device.

FIG. 12 shows a flow diagram illustrating another example process for manufacturing an EMS device.

FIGS. 13A and 13B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to an EMS device including a movable electrode and a stationary electrode separated by a gap therebetween. One of the electrodes is divided into two or more electrically isolated electrode segments, where each of the electrode segments connects to and corresponds to a distinct one of a plurality of TFTs. The plurality of TFTs are configured to drive the movable electrode to two or more positions across the gap towards the stationary electrode by application of a common voltage. The common voltage can be applied initially to move the movable electrode, and then the TFTs can isolate the electrodes so that a voltage for each electrode segment will independently vary depending on the position of the movable electrode. The plurality of TFTs combined with the isolated electrode segments can maintain a fixed charge in each of the electrode segments, which can reduce the effects of tilt instability. In some implementations, the EMS device includes a plurality of hinges connected to the movable electrode for supporting the movable electrode over the stationary electrode, where the plurality of hinges may be symmetrically arranged around the movable electrode. In some implementations, the EMS device can be a two-terminal EMS device. In some implementations, each of the TFTs can include a gate electrode connected to a gate line and a source/drain electrode connected to a data line, where each of the TFTs share the same gate line and data line.

Particular implementations of the subject matter described in this disclosure can be implemented to realize one or more of the following potential advantages. An EMS device with two-terminals is less complex to manufacture than an EMS device with three or more terminals, because the two-terminal EMS device may be manufactured without a top plate or multiple sacrificial layers. Also, the two-terminal EMS device can experience fewer complications in operation than an EMS device with three or more terminals. For example, a two-terminal EMS device can have a simpler drive scheme, simpler electronics, and simpler routing. In addition, a stationary or movable electrode with isolated electrode segments each connected to a distinct TFT prevents charge from moving that would lead to rotational instability in a movable electrode. A positively reinforcing mechanism caused by tilt instability is reduced by preventing charge from migrating to electrode segments with smaller gap sizes. Thus, as the gap size gets smaller for any electrode segment, the capacitance increases which then decreases the voltages, thereby decreasing the electrostatic pressure. Thus, the stable travel range of the EMS device is increased, adding greater precision and functionality to the EMS device without substantial reduction in total electrode area. In implementations where the EMS device is an IMOD, extending the stable travel range can extend the range of colors that can be reflected by the IMOD.

An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector (a.k.a. a mirror) that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber. However, if the reflector is tilted, the thickness of the optical resonant cavity becomes uneven, causing the color to become off in part of the IMOD. Thus, it is important to provide a reflector that is reflector that is resistant to tilt. By adopting at least some of the features disclosed herein, the reflector of the IMOD can be more resistant to tilting.

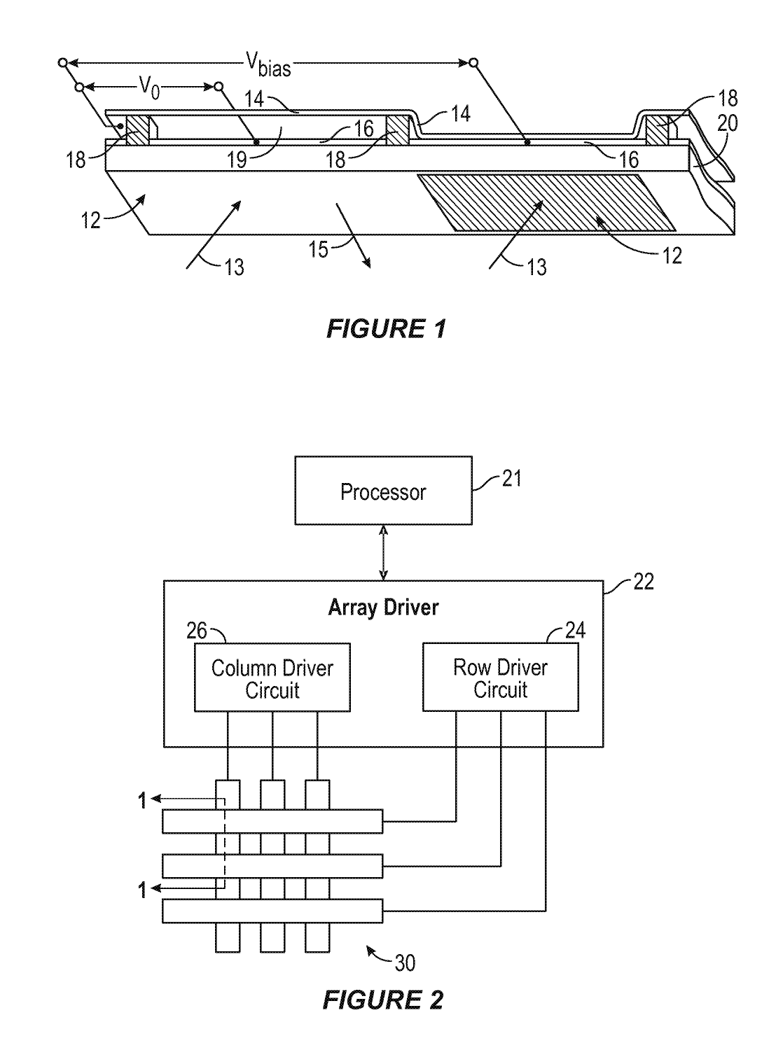

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex®, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa. The array driver 22 and the row driver circuit 24 may provide signals for actuating a movable mirror or movable electrode by a plurality of TFTs for an IMOD display element, where the movable mirror or movable electrode may be more tilt resistant in the present disclosure.

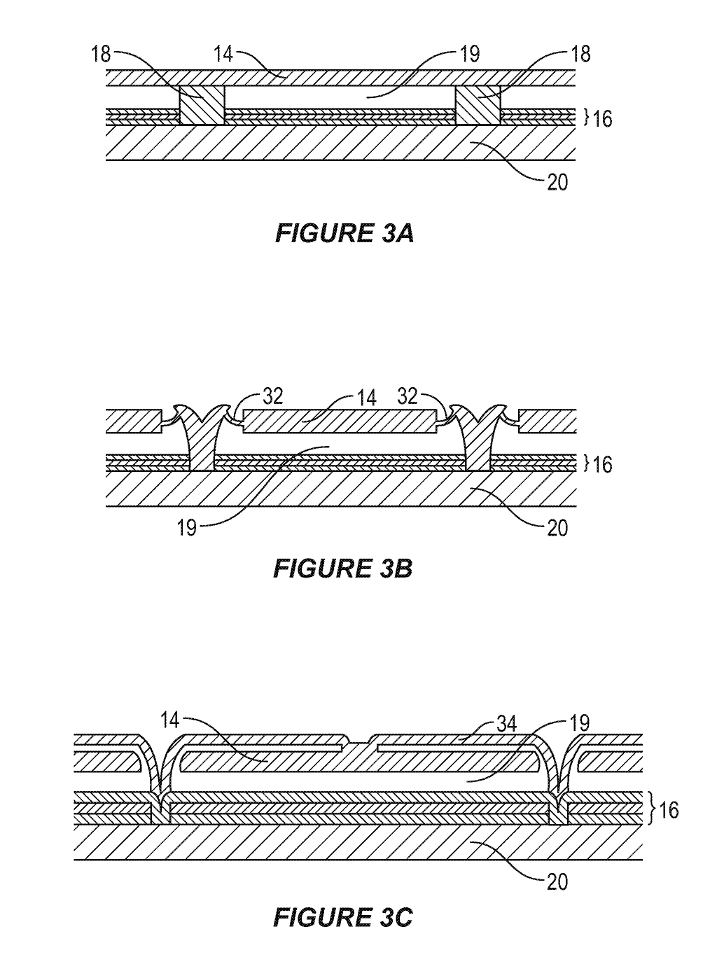

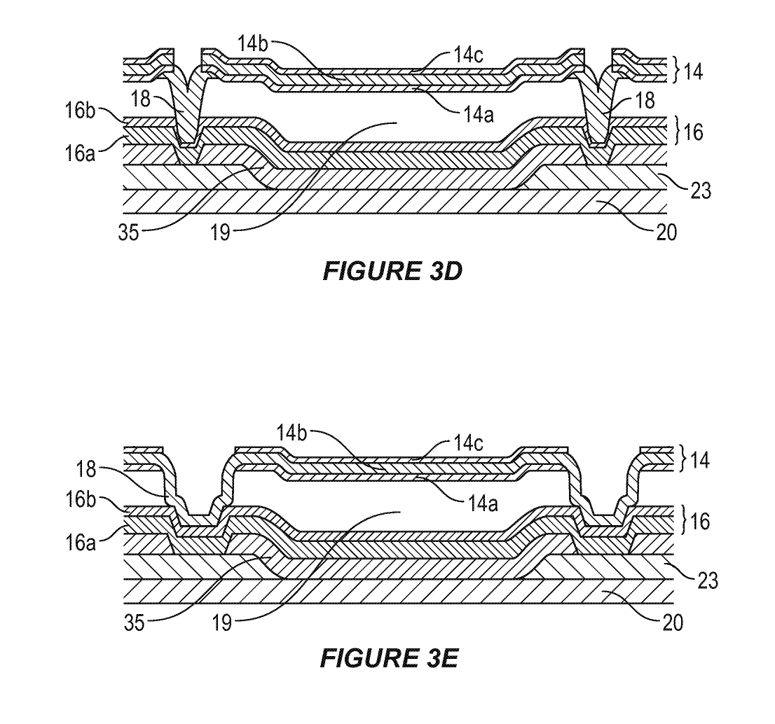

The details of the structure of IMOD displays and display elements may vary widely. FIGS. 3A-3E are cross-sectional illustrations of varying implementations of IMOD display elements. FIG. 3A is a cross-sectional illustration of an IMOD display element, where a strip of metal material is deposited on supports 18 extending generally orthogonally from the substrate 20 forming the movable reflective layer 14. In FIG. 3B, the movable reflective layer 14 of each IMOD display element is generally square or rectangular in shape and attached to supports at or near the corners, on tethers 32. In FIG. 3C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as implementations of “integrated” supports or support posts 18. The implementation shown in FIG. 3C has additional benefits deriving from the decoupling of the optical functions of the movable reflective layer 14 from its mechanical functions, the latter of which are carried out by the deformable layer 34. This decoupling allows the structural design and materials used for the movable reflective layer 14 and those used for the deformable layer 34 to be optimized independently of one another.

FIG. 3D is another cross-sectional illustration of an IMOD display element, where the movable reflective layer 14 includes a reflective sub-layer 14a. The movable reflective layer 14 rests on a support structure, such as support posts 18. The support posts 18 provide separation of the movable reflective layer 14 from the lower stationary electrode, which can be part of the optical stack 16 in the illustrated IMOD display element. For example, a gap 19 is formed between the movable reflective layer 14 and the optical stack 16, when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a and 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 3D, some implementations also can include a black mask structure 23, or dark film layers. The black mask structure 23 can be formed in optically inactive regions (such as between display elements or under the support posts 18) to absorb ambient or stray light. The black mask structure 23 also can improve the optical properties of a display device by inhibiting light from being reflected from or transmitted through inactive portions of the display, thereby increasing the contrast ratio. Additionally, at least some portions of the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. In some implementations, the black mask structure 23 can be an etalon or interferometric stack structure. For example, in some implementations, the interferometric stack black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, tetrafluoromethane (or carbon tetrafluoride, CF₄) and/or oxygen (O₂) for the MoCr and SiO₂ layers and chlorine (Cl₂) and/or boron trichloride (BCl₃) for the aluminum alloy layer. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate electrodes (or conductors) in the optical stack 16 (such as the absorber layer 16a) from the conductive layers in the black mask structure 23.

FIG. 3E is another cross-sectional illustration of an IMOD display element, where the movable reflective layer 14 is self-supporting. While FIG. 3D illustrates support posts 18 that are structurally and/or materially distinct from the movable reflective layer 14, the implementation of FIG. 3E includes support posts that are integrated with the movable reflective layer 14. In such an implementation, the movable reflective layer 14 contacts the underlying optical stack 16 at multiple locations, and the curvature of the movable reflective layer 14 provides sufficient support that the movable reflective layer 14 returns to the unactuated position of FIG. 3E when the voltage across the IMOD display element is insufficient to cause actuation. In this way, the portion of the movable reflective layer 14 that curves or bends down to contact the substrate or optical stack 16 may be considered an “integrated” support post. One implementation of the optical stack 16, which may contain a plurality of several different layers, is shown here for clarity including an optical absorber 16a, and a dielectric 16b. In some implementations, the optical absorber 16a may serve both as a stationary electrode and as a partially reflective layer. In some implementations, the optical absorber 16a can be an order of magnitude thinner than the movable reflective layer 14. In some implementations, the optical absorber 16a is thinner than the reflective sub-layer 14a.

Aspects of the implementations show in FIGS. 3A-3E can be part of the EMS device of the present disclosure. For example, a movable reflective layer 14 can be incorporated in the EMS device of the present disclosure, where the movable reflective layer 14 can include one or more sub-layers. Also, the movable reflective layer 14 can be supported by tethers 32, deformable layer 34, and/or support posts 18. In some implementations, hinges as discussed below may include the tethers 32, deformable layer 34, and/or support posts 18. Though the movable reflective layer 14 in FIGS. 3A-3E may be subject to tilt instability, the EMS device of the present disclosure may include a more tilt-resistant movable reflective layer 14.

In implementations such as those shown in FIGS. 3A-3E, the IMOD display elements form a part of a direct-view device, in which images can be viewed from the front side of the transparent substrate 20, which in this example is the side opposite to that upon which the IMOD display elements are formed. In these implementations, the back portions of the device (that is, any portion of the display device behind the movable reflective layer 14, including, for example, the deformable layer 34 illustrated in FIG. 3C) can be configured and operated upon without impacting or negatively affecting the image quality of the display device, because the reflective layer 14 optically shields those portions of the device. For example, in some implementations a bus structure (not illustrated) can be included behind the movable reflective layer 14 that provides the ability to separate the optical properties of the modulator from the electromechanical properties of the modulator, such as voltage addressing and the movements that result from such addressing.

For many EMS and MEMS devices, a voltage can be applied to generate an electrostatic attraction between two electrodes of the device. The electrostatic force between the two electrodes is inversely proportional to separation distance between the two electrodes, and can increase quadratically as the separation distance decreases. As a movable electrode is driven towards a stationary electrode, the movable electrode can become unstable after the movable electrode travels a certain distance, and the movable electrode can travel the remaining separation distance without any additional stimulus or perturbation. This phenomenon can be referred to as “snap-through.”

Moreover, if the movable electrode tilts by even the slightest degree, which can be caused by any asymmetry in the movable electrode or the slightest asymmetric perturbation, charge can build up in the area of the tilt and lead to a positively reinforcing mechanism. This mechanism contributes to tilt instability of the movable electrode. Thus, the range of stable travel positions through which the movable electrode can be electrostatically displaced can be limited at least in part by a tendency of the movable electrode to tilt. The tendency to tilt can result from any asymmetry in the EMS device, such as variances or imperfections in the manufacture of the EMS device. A slight rotational instability can lead to unintended “snap-through” or collapse of an electrostatically displaced movable electrode towards the stationary electrode when the movable electrode is near the edge of a stable range of positions. This can be due, in part, to imbalanced charge accumulation on the movable electrode which leads to tilting and subsequent collapse of the movable electrode. Therefore, beyond a certain critical travel range or tilt angle, the tilting becomes unstable and one side or corner of the device can collapse or snap-through. For example, after the movable electrode travels at least half of the distance between two electrodes, the tilting can become unstable in the EMS device. The distance between two electrodes, such as the movable electrode and the stationary electrode, can be referred to as an “electrical gap.” An issue like tilt instability can limit the range of stable positions of EMS devices, which limits the performance of the EMS device.

Some EMS devices may include optical devices, such as IMODs, as discussed earlier herein. By way of an example, an IMOD can have a stable range from an initial electrical gap at about 540 nm (e.g., green) to about 360 nm (e.g., red). Hence, the IMOD can tune continuously within the red-green-blue (RGB) color spectrum from about 360 nm to about 540 nm. In another example, an IMOD can have a stable range from an initial electrical gap at about 350 nm (e.g., blue), to about 250 nm (e.g., red), and to about 170 nm (e.g., green). Hence, the IMOD can tune continuously within the RGB color spectrum from about 350 nm to about 170 nm. It will be understood that the standard range of positions for color generation may vary depending on the design of the IMOD. Beyond the stable range of positions, tuning the IMOD to generate various wavelengths of light, such as black may be difficult. Even if some IMODs try to extend the stable region in the electrical gap by driving with charge instead of voltage, or adding a capacitor in series, such configurations of IMODs can still be subject to tilt instability.

IMODs 12 of FIG. 1 are illustrated in two positions, a relaxed position in which no voltage is applied between the movable layer 14 and the optical stack 16, and an actuated state in which a voltage sufficient to collapse the movable layer 14 against the optical stack 16 has been applied. However, an IMOD 12 also may be driven in a multi-state, or an analog or near-analog, manner. An EMS device such as IMOD 12 may function essentially as a parallel plate capacitor in which one of the electrodes is movable relative to another electrode. A movable electrode such as the movable layer 14 can move to an equilibrium position between an electrostatic force and a restoring force. The electrostatic force can result from a voltage difference between the movable electrode and a stationary electrode such as the optical stack 16. The restoring force can result at least in part from the displacement of the movable layer 14 from a resting position. In some implementations, the movable layer 14 may be referred to as a movable electrode, a movable reflective layer, a mirror, or a movable mirror. However, even though certain implementations may refer to a mirror or a movable mirror, it will be understood that the description of those implementations is not necessarily intended to exclude other limitations in which a movable layer may be less reflective or otherwise less suitable as a mirror.

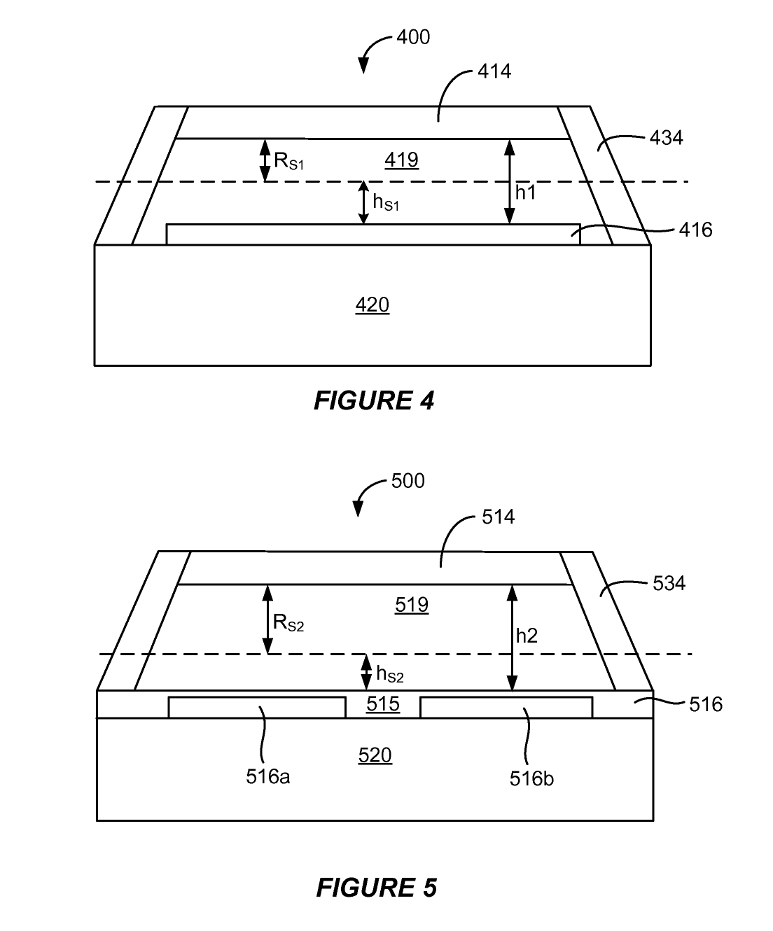

FIG. 4 shows a cross-sectional schematic diagram of an example two-terminal EMS device with unsegmented electrodes. A two-terminal EMS device 400 can include two electrodes 414 and 416, where a movable electrode 414 is positioned over a stationary electrode 416 and separated by a gap 419. The stationary electrode 416 can be disposed on a substrate 420. The movable electrode 414 can be supported by a plurality of hinges 434 and over the stationary electrode 416, where the hinges 434 can be connected at the edges or corners of the movable electrode 414. A voltage source (not shown) can apply a voltage to the two-terminal EMS device 400 between the movable electrode 414 and the stationary electrode 416, which creates an electrostatic force on the movable electrode 414 to move the movable electrode 414 across the gap 419 towards the stationary electrode 416. In some implementations, the movable electrode 414 is configured to move to two or more positions across the gap 419 towards the stationary electrode 416. In FIG. 4, neither the movable electrode 414 nor the stationary electrode 416 is segmented. The two-terminal EMS device 400 can have a stable range Rₛ₁ so that application of a voltage less than an actuation voltage of the two-terminal EMS device 400 can cause the movable electrode 414 to move within the stable range Rₛ₁. The stable range Rₛ₁ can constitute the range of positions between the maximum height h1 and the minimum stability height hₛ₁. Beyond the stable range Rₛ₁, the two-terminal EMS device 400 can experience tilt instability or snap-through. If the applied voltage is equal to or exceeds the actuation voltage of the two-terminal EMS device 400, the movable electrode 414 will collapse against the stationary electrode 416.

In implementations where the two-terminal EMS device 400 is an IMOD, as the movable electrode 414 is moved towards the stationary electrode 416, the height of the gap 419 between the movable electrode 414 and the stationary electrode 416 will change, and a color reflected by the IMOD will vary. An IMOD driven in a multi-state manner can therefore provide a particular color in response to application of a particular voltage. However, the limited stable range Rₛ₁ can place constraints on the range of possible colors for the IMOD. To provide an increased stable range, some IMODs may include three terminals, but a three-terminal EMS device may introduce complications with multiple electrodes and may be more costly to manufacture than a two-terminal EMS device.

In some implementations of the two-terminal EMS device 400, the stable range Rₛ₁ can be one-third of the maximum height h1. Beyond one-third of the maximum height h1, the movable electrode 414 may snap-through the remainder of the gap 419. In some implementations, the stable range Rₛ₁ can be increased, such as by incorporating a series capacitor in the two-terminal EMS device 400. However, the stable range Rₛ₁ can still be limited by the effects of tilt instability. In some implementations, for example, the stable range Rₛ₁ can be one-half of the maximum height h1 before the two-terminal EMS device 400 experiences tilt instability. Hence, the stable range Rₛ₁ can be effectively limited by the effects of snap-through and tilt instability.

FIG. 5 shows a cross-sectional schematic diagram of an example two-terminal EMS device with a movable electrode over a stationary electrode, where the stationary electrode has two or more electrically isolated electrode segments. A two-terminal EMS device 500 includes two electrodes 514 and 516, where a movable electrode 514 is positioned over a stationary electrode 516 and separated by a gap 519 therebetween. The stationary electrode 516 can be disposed on a substrate 520. The substrate can include any suitable substrate material, such as a glass, plastic, or semiconducting material. The movable electrode 514 can be supported over the stationary electrode 516 by a plurality of hinges 534, where the hinges 534 can be connected at the corners or edges of the movable electrode 514. In some implementations, the hinges 534 can be symmetrically arranged about the center of the movable electrode 514.

As used herein, reference to terms such as “stationary electrode” and “movable electrode” can refer to structures including one or more layers or sublayers. In some implementations, a stationary electrode can include multiple layers, such as one or more of an electrically conductive layer, a partially absorbing layer, and a transparent dielectric layer, an example of which is shown in the optical stack 16 of FIG. 1. In some implementations, a movable electrode can include multiple layers, such as one or more of an electrically conductive layer, a partially reflective layer, and a transparent dielectric layer, an example of which is shown in the reflective layer 14 of FIG. 1. However, in some other implementations, the movable electrode can include the partially absorbing layer and the stationary electrode can include the partially reflective layer.

A voltage source (not shown) can apply a voltage to the two-terminal EMS device 500 between the movable electrode 514 and the stationary electrode 516, which creates an electrostatic force on the movable electrode 514 to move the movable electrode 514 to two or more positions across the gap 519 towards the stationary electrode 516. As illustrated in FIG. 5, the stationary electrode 516 can be divided into electrically isolated electrode segments 516a and 516b. It will be understood that the stationary electrode 516 is not limited to two electrically isolated electrode segments 516a and 516b, but can be divided into more than two electrode segments.

In some implementations, the electrode segments 516a and 516b can be symmetrical to each other. In some implementations, the electrode segments 516a and 516b can be symmetrical along one or more axes defining the plane of the electrode 516. The axes can be perpendicular to each other and can define axes of rotation of the movable electrode 514. For example, the stationary electrode 516 can be divided into four electrically isolated electrode segments. Four electrode segments, when divided evenly along an x-axis and y-axis, can be provide greater stability in the two-terminal EMS device 500 so that one or more electrode segments may not be more subject to tilt along the x-axis or the y-axis than the other electrode segments. Electrode segments 516a and 516b can be identical in electrode area and symmetric about the center of the stationary electrode 516. Generally, having the electrode segments 516a and 516b identical in electrode area and symmetrical can be more effective in increasing the stable range of the two-terminal EMS device 500 than not having electrode segments 516a and 516b that are identical and symmetrical. That way, one electrode segment is not more prone to tilt than the other. Nonetheless, it will be understood that the electrode segments 516a and 516b need not be identical or symmetrical. In such implementations, the stable range of the two-terminal EMS device 500 can still be increased. Also, it will be understood that the two-terminal EMS device 500 is not limited to dividing the stationary electrode 516, but can alternatively have the movable electrode 514 divided into two or more electrically isolated electrode segments.

The two-terminal EMS device 500 can have a stable range Rₛ₂ so that application of a voltage less than an actuation voltage of the two-terminal EMS device 500 can cause the movable electrode 514 to move within the stable range Rₛ₂. The stable range Rₛ₂ can constitute the range of stable positions between a maximum height h2 and a minimum stability height hₛ₂. If the applied voltage is equal to or exceeds the actuation voltage of the two-terminal EMS device 500, the movable electrode 514 will collapse against the stationary electrode 516.

The electrode segments 516a and 516b can be electrically isolated by a dielectric layer 515. In some implementations, the dielectric layer 515 can surround the electrode segments 516a and 516b in the stationary electrode 516, where the dielectric layer 515 can be disposed on the substrate 520. In some implementations, the dielectric layer 515 can have a thickness equal to or greater than a thickness of the electrode segments 516a and 516b. Where the thickness of the dielectric layer 515 exceeds a thickness of the electrode segments 516a and 516b, the stable range Rₛ₂ may be increased because the electrical gap between the electrodes 514 and 516 is greater than the maximum gap height h2.

Typically, when a movable electrode includes electrically isolated electrode segments, a stable range of an EMS device can be increased. When the movable electrode begins to tilt, the amount of charge that shifts to the outer edges of the electrode segments is less than if the movable electrode included a single, undivided electrode. For example, if the movable electrode were separated into four electrode segments, the amount of charge that would shift to the outer edges of the electrode segment closest to the stationary electrode could be on the order of half the charge that would shift to the outer edge of single, undivided electrode. However, the amount of charge that could shift to the outer edge can vary in different implementations. Nonetheless, the division of charge accumulation can occur because the charge on the more distant electrode segment not tilted towards the undivided stationary electrode cannot move across the dielectric material separating the electrode segments. By inhibiting charge accumulation in such a manner in the movable electrode, the movable electrode can be more tilt-resistant and can increase the stable range of the EMS device. In some implementations, one electrode can include an undivided electrode, such as a driving electrode, and a plurality of electrode segments, where the plurality of electrode segments are separated from one another and separated from the undivided electrode. For example, a movable electrode can include a driving electrode over two or more electrode segments, where dielectric material separates the driving electrode from the two or more electrode segments, and where the two or more electrode segments are electrically isolated from one another. A more detailed description of an example EMS device with segmented electrodes in a movable layer is provided in U.S. patent application Ser. No. 13/804,261 to Chan et al., filed Mar. 14, 2013 and entitled “Electromechanical Systems Device with Segmented Electrodes,” the entirety of which is incorporated by reference herein for all purposes.

The segmented electrodes as described above may be electrically isolated and “floating.” In other words, such segmented electrodes may be disposed between a driving electrode and a stationary electrode without any electrical connections. This effectively creates a capacitor in series that can extend the stable range of the electrical gap.

In FIG. 5, the EMS device 500 can be considered as a capacitor formed by the movable electrode 514 and the stationary electrode 516 separated by the gap 519. Generally, capacitance is inversely proportional to the size of the gap 519. When one portion of the movable electrode 514 tilts, the size of the gap 519 from that portion to the stationary electrode 516 decreases so that capacitance increases. Capacitance (C) can be calculated as charge (Q) divided by the potential difference (V):

C=Q/V.

Pressure (p), or electrostatic force between two electrodes per unit area, is proportional to the voltage or potential difference:

P=F/A=−∈V²/2z².

Accordingly, when a portion of the movable electrode 514 tilts, voltage decreases between the two electrodes 514 and 516, which can lead to a less negative (more positive) pressure between the two electrodes 514 and 516 during actuation.

In FIG. 5, the stationary electrode 516 can be divided into electrically isolated electrode segments 516a and 516b to limit the flow of charge between the electrode segments 516a and 516b. Alternatively, the movable electrode 514 can be divided into electrically isolated electrode segments to limit the flow of charge between the electrode segments. Not only can the flow of charge between electrode segments 516a and 516b be limited, but the amount of charge applied in each of the segments 516a and 516b can be controlled during actuation. Electrical connections and circuitry can be applied to the electrode segments 516a and 516b so that a voltage can be directly applied to the electrode segments 516a and 516b. A voltage can be applied to the electrode segments 516a and 516b initially before the movable electrode 514 moves substantially. In other words, the voltage can be applied for a very short duration that is common to all the electrode segments 516a and 516b. When the movable electrode 514 moves towards the stationary electrode 516, the common voltage can be turned off or disconnected so that there can be electrical isolation between electrode segments 516a and 516b. Thus, each electrode segment 516a and 516b can take on its own voltage. The capacitance increases depending on the separation between any one of the electrode segments 516a and 516b and the movable electrode 514. As a result, the voltage in each of the electrode segments 516a and 516b decreases, where each electrode segment 516a and 516b can have its own voltage. The decreased voltage can contribute to a more positive (less negative) pressure between the two electrodes 514 and 516 during actuation. When tilt is prevented, the voltage in each of the electrode segments 516a and 516b should be equal.

In some implementations, the mechanism for driving the two-terminal EMS device 500 can be achieved by a plurality of TFTs (not shown), where each of the TFTs can be connected to and corresponding to a distinct one of the electrically isolated electrode segments 516a and 516b. The TFTs can be configured to maintain constant charge in each of the electrically isolated electrode segments 516a and 516b. Even though the stationary electrode 516 is segmented, the plurality of TFTs can apply a common voltage to drive the movable electrode 514 to two or more positions across the gap 519. The TFTs apply a common voltage, and then provide isolation between the electrodes 514 and 516 after the voltage is applied and the movable electrode 514 begins to move. A common voltage may be associated with a single or common signal provided to the plurality of TFTs. In some implementations, the plurality of TFTs may share a common source for providing the common voltage, such as a shared gate line and/or shared data line, as discussed in more detail below. When electrode segments 516a and 516b are connected to TFTs to drive the two-terminal EMS device 500 and maintain a constant charge in each of the electrode segments 516a and 516b, the stable range Rₛ₂ in FIG. 5 can be increased, where Rₛ₂ can be greater than Rₛ₁ in FIG. 4. The stable range Rₛ₂ can represent the range of stable positions in which application of the common voltage by the plurality of TFTs moves the movable electrode 514 to a position within the range of stable positions. In some implementations, for example, Rₛ₂ can be greater than 50% of the maximum height h2 of the gap 519, greater than 75% of the maximum height h2 of the gap 519, or greater than 85% of the maximum height h2 of the gap 519. Where the two-terminal EMS device 500 is an IMOD, the increased stable range Rₛ₂ can provide a wide range of possible colors for the IMOD.

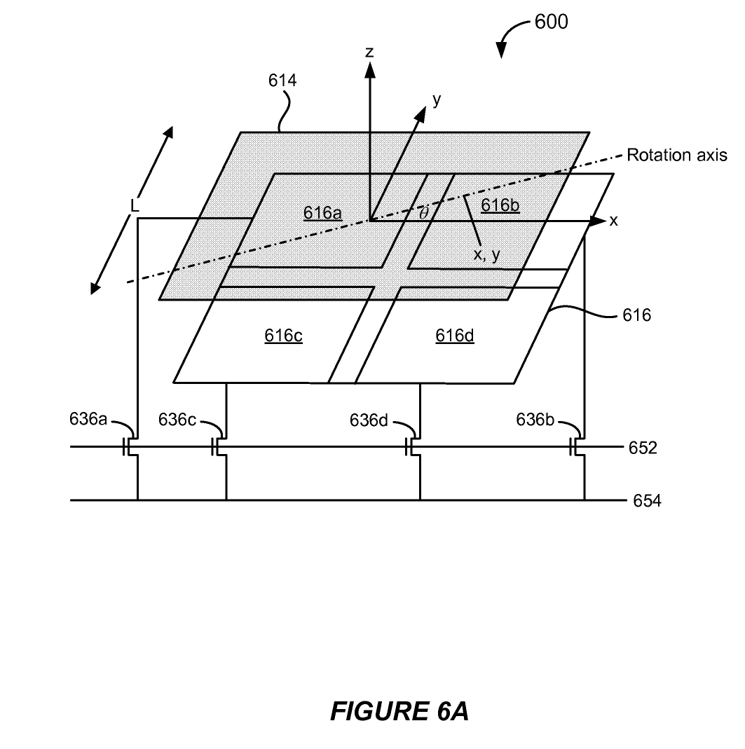

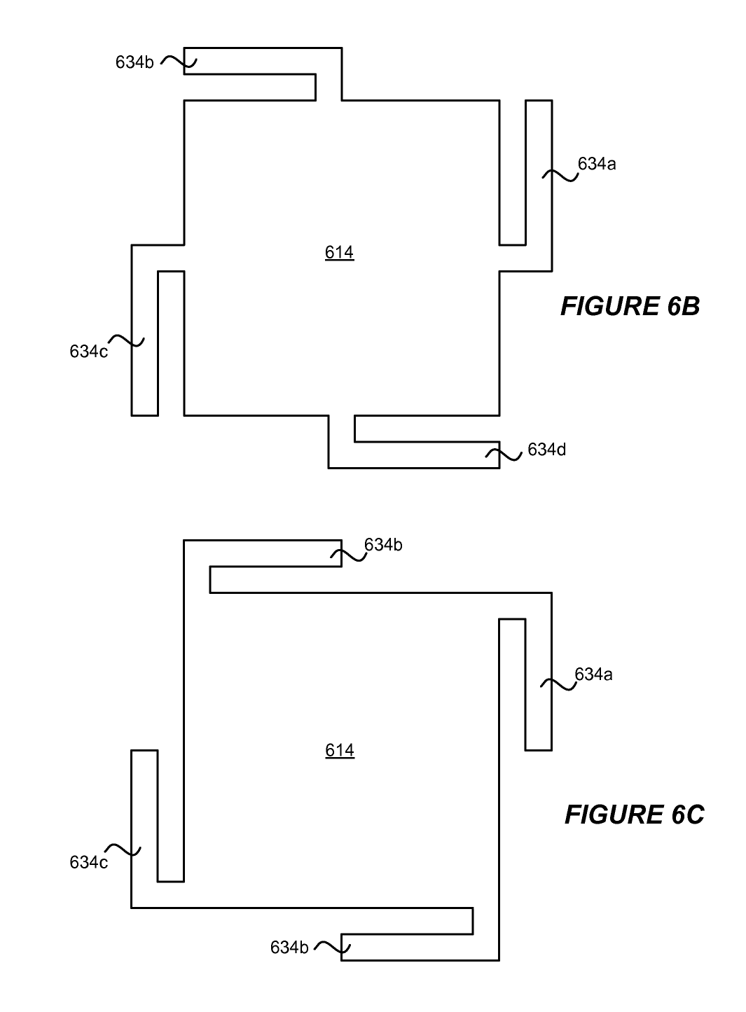

FIG. 6A shows a perspective schematic diagram of an example two-terminal EMS device with an electrode segmented into four quadrants. The two-terminal EMS device 600 includes two electrodes 614 and 616, where one of the electrodes can be movable or connected to a movable layer, and the other electrode can be stationary or connected to a stationary layer. A first electrode 616 can be divided into four quadrants 616a, 616b, 616c, and 616d that are electrically isolated from one another so that charge cannot flow across from one quadrant to another. The two-terminal EMS device 600 further includes four TFTs 636a, 636b, 636c, and 636d, where each of the quadrants 616a, 616b, 616c, and 616d connect to and correspond to a distinct TFT 636a, 636b, 636c, and 636d.

The two-terminal EMS device 600 can further include a gate line 652 electrically coupled to the plurality of TFTs 636a, 636b, 636c, and 636d, and a data line 654 electrically coupled to the plurality of TFTs 636a, 636b, 636c, and 636d. Each of the plurality of TFTs 636a, 636b, 636c, and 636d share the gate line 652 and share the data line 654. Hence, rather than each of the TFTs 636a, 636b, 636c, and 636d applying a separate signal/voltage to each of the quadrants 616a, 616b, 616c, and 616d, the plurality of TFTs 636a, 636b, 636c, and 636d apply a common voltage to the quadrants 616a, 616b, 616c, and 616d. The common voltage can come from a signal provided by either of the gate line 652 or the data line 654. In other words, the gate line 652 or the data line 654 is configured to provide a signal associated with the common voltage. That way, different signals or voltages are not used to drive the quadrants 616a, 616b, 616c, and 616d of the first electrode 616. The common voltage is applied through the plurality of TFTs 636a, 636b, 636c, and 636d to drive the second electrode 614 towards the first electrode 616. The common voltage that is applied through the plurality of TFTs 636a, 636b, 636c, and 636d can be applied for a short duration, which can be shorter than the time it takes for second electrode 614 to substantially move. Thus, the voltage is common to the quadrants 616a, 616b, 616c, and 616d while the TFTs 636a, 636b, 636c, and 636d are connecting the electrodes 614 and 616. The TFTs 636a, 636b, 636c, and 636d may be considered “on” when the common voltage is applied. When the second electrode 614 is moving towards the first electrode 616, the TFTs 636a, 636b, 636c, and 636d may be disconnected or considered “off” Then the voltage for each quadrant 616a, 616b, 616c, and 616d will vary depending on the position of the second electrode 614, which determines its capacitance. Since each quadrant 616a, 616b, 616c, and 616d is independent when the TFTs 636a, 636b, 636c, and 636d are disconnected, each quadrant 616a, 616b, 616c, and 616d can have its own voltage. When tilting is prevented, the voltages for the quadrants 616a, 616b, 616c, and 616d are equal to one another.

The plurality of TFTs 636a, 636b, 636c, and 636d can maintain a constant charge in each of the quadrants 616a, 616b, 616c, and 616d, where the quadrants 616a, 616b, 616c, and 616d are electrically isolated from one another and can prevent charge from migrating to other quadrants 616a, 616b, 616c, and 616d with smaller gap sizes. The plurality of TFTs 636a, 636b, 636c, and 636d can be configured to maintain a fixed charge in each of the quadrants 616a, 616b, 616c, and 616d when the second electrode 614 is driven across the gap between the two electrodes 614 and 616. In some implementations, the gate line 652 can be in electrical communication with a row driver circuit 24 for providing a signal to a display array or panel 30 in FIG. 2, and the data line 654 can be in electrical communication with a column driver circuit 26 for providing a signal to the display array or panel 30 in FIG. 2. The gate line 652 may be patterned as parallel strips and form row electrodes in the EMS device 600, and the data line 654 may be patterned as parallel strips and form column electrodes in the EMS device 600.

In some implementations, each of the TFTs 636a, 636b, 636c, and 636d can include a gate electrode, a semiconductor layer, and a source/drain electrode. The gate electrode, the semiconductor layer, and the source/drain electrode of the TFT can be arranged according to any suitable TFT design known in the art, such as top-gate or bottom-gate TFTs, planar TFT or staggered TFT, amorphous silicon TFTs or low-temperature polysilicon TFTs, etc. In some implementations, the gate electrode can be configured to receive a first signal from the gate line 652 associated with the common voltage. In some implementations, the source/drain electrode can be configured to receive a second signal from the data line 654 associated with the common voltage. The source/drain electrode may be patterned so that a source electrode corresponds to a source region in the semiconductor layer and a drain electrode corresponds to drain region in the semiconductor layer. The semiconductor layer can include a channel region between the source region and the drain region. In some implementations, the semiconductor layer can be an active layer that includes a metal oxide semiconducting material, such as indium-gallium-zinc-oxide.

As illustrated in FIG. 6A, a second electrode 614 can be movable so that the second electrode 614 is configured to move along a vertical direction (z-direction) towards the first electrode 616 and is capable of tilting by a tilt angle Φ according to the equation:

z(x,y)=z(0,0)+(−x sin θ+y cos θ)Φ.

A tilt axis (rotation axis) can lie in the x-y plane of the second electrode 614 along an angle θ. Torque (T) is a measure of the applied force multiplied by a distance to the tilt axis. Tilt stability can be measured by the change in torque over the change in tilt angle defined by the following equation:

dT/dΦ=∫∫dp/dΦ(−x sin θ+y cos θ)dxdy.

The stable condition occurs where dT/dΦ<0.

As mentioned above, any asymmetry in the two-terminal EMS device 600 or any slight asymmetric perturbation can lead to rotational instability of the second electrode 614, leading to a positively reinforcing mechanism so that the second electrode 614 becomes increasingly imbalanced during actuation. Hence, if one side tilts down slightly, the force on that side increases, and the tilt increases even more. The positively reinforcing mechanism produces a positive value for dT/dΦ. Thus, introducing a negative value for dT/dΦ into the design or operation of the two-terminal EMS device 600 can provide a restoring force that limits the effect of tilt instability, thereby increasing the stable range of the two-terminal EMS device 600.

Vertical position (z) changes as a function of tilt angle Φ and potential difference V changes as a function of tilt angle Φ. The tilt stability of the two-terminal EMS device 600 can be determined by two terms:

dTₑ₁/dΦ=∫∫(dp/dz)(dz/dΦ)(−x sin θ+y cos θ)dxdy,

dTₑ₂/dΦ=∫∫(dp/dV)(dV/dΦ)(−x sin θ+y cos θ)dxdy.

The first term is a positive value. If one side tilts down, then electrostatic attraction between the two electrodes 614 and 616 increases, and then the force on that side increases so that it tends to tilt more. Pressure increases as vertical position decreases, and vertical position decreases as tilt angle increases. After integration, the overall sign is positive. Thus, this first term may be referred to as a “positive feedback” term. For a square plate with each side having a length L, the first term can be:

dTₑ₁/dΦ=∈V²L⁴/12z³.

The second term can be a negative value. Capacitance increases as one side tilts down. The increased capacitance can cause the voltage to decrease. Additionally, the voltage can decrease with increased capacitance when charge is held constant. Voltage decreases as tilt angle increases, and pressure decreases as voltage decreases. After integration, the overall sign is negative. Therefore, this second term may be referred to as a “negative feedback” term. How negative the negative feedback term is can depend on the voltage potential between the two electrodes 614 and 616. After introducing a common voltage between two electrodes 614 and 616, the multiple TFTs can be disconnected or turned off so that each quadrant 616a, 616b, 616c, and 616d can take on its own voltage and maintain a constant charge across each quadrant 616a, 616b, 616c, and 616d. This can lead to a reduced electrostatic pressure in particular quadrants 616a, 616b, 616c, and 616d that can provide a more negative feedback term to counteract against the positive feedback term caused by tilt instability. For a square plate with each side having a length L and where charge is constant, the second term can be:

dTₑ₂/dΦ=−∈V²L⁴/16z³.

FIG. 6B shows a schematic top view of a movable electrode with four hinges connected at the edges of the movable electrode for the example two-terminal EMS device of FIG. 6A. FIG. 6C shows a schematic top view of a movable electrode with four hinges connected at the corners of the movable electrode for the example two-terminal EMS device of FIG. 6A. The hinges 634a, 634b, 634c, and 634d may serve to support the second electrode 614 over the first electrode 616. The hinges 634a, 634b, 634c, and 634d may be symmetrically arranged about the center of the second electrode 614.

In some implementations, the tilt stability of the two-terminal EMS device 600 can be determined by one or more additional terms. For example, hinges 634a, 634b, 634c, and 634d can connect to the edges of the second electrode 614 as shown in FIG. 6B. Where the second electrode 614 is a square plate having a length L, a plurality of four hinges 634a, 634b, 634c, and 634d may connect to the edges of the second electrode 614 in the x-y plane at (L/2, 0), (0, L/2), (−L/2, 0), and (0, −L/2). Each of the hinges 634a, 634b, 634c, and 634d may provide a restoring force of: F=−k(z−zₒ), where zₒ is the launch position. In some implementations, the launch position zₒ may correspond to the maximum height of the gap between the two electrodes 614 and 616, or the height of the gap between the two electrodes 614 and 616 prior to actuation. Assuming the hinges 634a, 634b, 634c, and 634d have some basic symmetry, the tilt stability attributable to the hinges 634a, 634b, 634c, and 634d can be calculated as the following:

dT/dΦ=−kΣ(z−zₒ)².

Where the hinges 634a, 634b, 634c, and 634d are connected at the edges of the second electrode 614, the term can be negative and determined to be:

dT/dΦ=−kL²/2.

By way of another example, hinges 634a, 634b, 634c, and 634d may connect to the corners of the second electrode 614 as shown in FIG. 6C. Where the second electrode 614 is a square plate with each side having a length L, the plurality of four hinges 634a, 634b, 634c, and 634d may connect to the corners of the second electrode 614 in the x-y plane at (L/2, L/2), (−L/2, L/2), (−L/2, −L/2), and (L/2, −L/2). The term can be negative and provide twice the amount of restoring force compared to hinges 634a, 634b, 634c, and 634d connected at the edges of the second electrode 614, where the term is determined to be:

dT/dΦ=−kL².

A tilt stable condition can be calculated for the two-terminal EMS device 600 with edge connections in FIG. 6B as:

−kL²/2+∈V²L⁴/12z³−∈V²L⁴/16z³<0,

which can be simplified to z>(1/4)zₒ. A tilt stable condition can be calculated for the two-terminal EMS device 600 with corner connections in FIG. 6C as:

−kL²+∈V²L⁴/12z³−∈V²L⁴/16z³<0,

which can be simplified to z>(1/7)zₒ. Thus, the two-terminal EMS device 600 can have an increased stable range, where the two-terminal EMS device 600 is stable at all positions up to ¼ of the initial launch position zₒ for edge connections in FIG. 6B, and where the two-terminal EMS device 600 is stable at all positions up to 1/7 of the initial launch position zₒ for corner connections in FIG. 6C. So if the initial launch position of the two-terminal EMS device 600 is 480 nm, then the two-terminal EMS device 600 can be stable up to 120 nm for edge connections in FIG. 6B, and stable up to 70 nm for corner connections in FIG. 6C. Where the two-terminal EMS device 600 is an IMOD, a wider range of colors can be generated with an increased stable range and a lower over-drive voltage can achieve a white state.

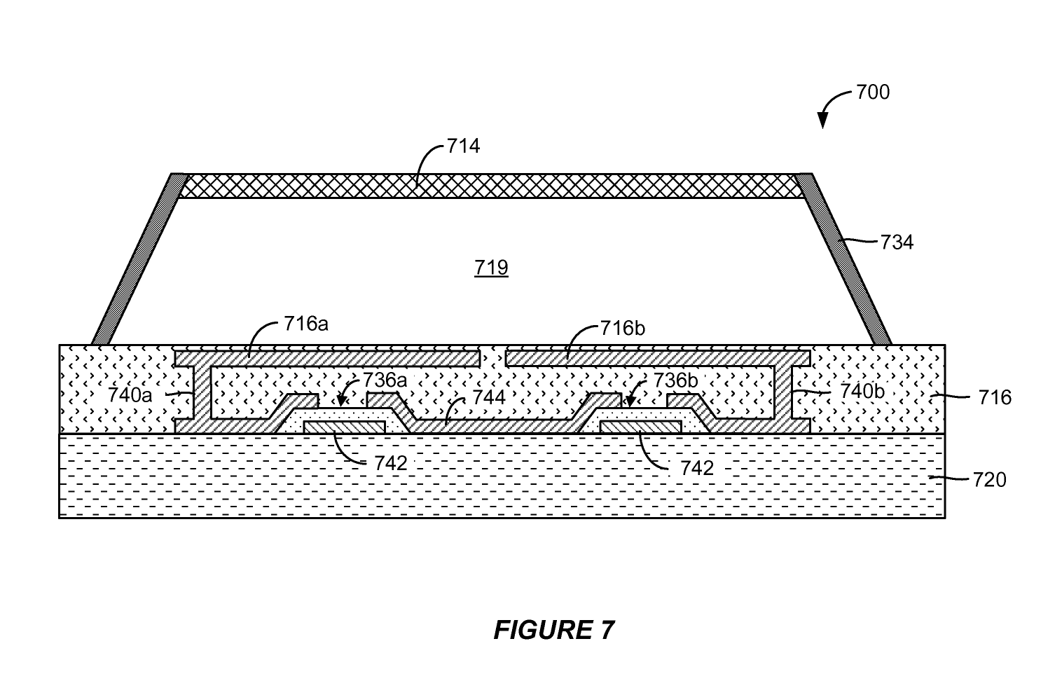

FIG. 7 shows a cross-sectional schematic diagram of an example EMS device with a stationary electrode having two or more electrically isolated electrode segments each connected to a TFT. An EMS device 700 can include a movable electrode 714 over a stationary electrode 716 and separated by a gap 719 therebetween. The stationary electrode 716 can be disposed on a substrate 720. The movable electrode 714 can move towards the stationary electrode 716 upon application of an electrostatic force. The movable electrode 714 can move across the gap 719 by electrostatic actuation to multiple positions in the gap 719. The EMS device 700 can include a plurality of hinges 734 connected to the movable electrode 714, where the movable electrode 714 can be supported over the stationary electrode 716 by the hinges 734. In some implementations, the hinges 734 can be connected at the corners of the movable electrode 714 and symmetrically arranged about the center of the movable electrode 714. In some implementations, the EMS device 700 can be an IMOD in a reverse IMOD configuration, where the movable electrode 714 can include an absorber facing a viewing side and the stationary electrode 716 can include a mirror or mirror segments facing a rear side opposite the viewing side. For example, the absorber can include molychrome or other material configured to at least partially absorb light, and the mirror can include aluminum or other material configured to at least partially reflect light. In some implementations, the EMS device 700 can be a two-terminal EMS device without a top plate.

The stationary electrode 716 can include two or more electrically isolated electrode segments 716a and 716b. The electrode segments 716a and 716b may be separated by dielectric material so that each of the electrode segments 716a and 716b are electrically isolated from one another, and charge cannot flow across from one electrode segment to another. The size or amount of dielectric material between the electrode segments 716a and 716b can be relatively small, such as a thickness of a few microns or less, or a thickness of less than about one micron depending on the process tolerance. That way, an appreciable reduction in total electrode area of the stationary electrode 716 can be avoided or at least minimized. In some implementations, the electrode segments 716a and 716b can be symmetrical to one another. In some implementations, the stationary electrode 716 can be divided into four or more electrode segments, where the four or more electrode segments can constitute quadrants in a square plate as illustrated in the implementation in FIG. 6A. For example, the stationary electrode 716 can include a mirror or conductive plate separated into at least four parts. In some implementations, the at least four parts can be identical in electrode area and symmetric about the center of the stationary electrode 716.

The EMS device 700 can further include two or more TFTs 736a and 736b, where each of the TFTs 736a and 736b connect to and correspond to a distinct one of the electrode segments 716a and 716b. Each of the TFTs 736a and 736b may be disposed over the substrate 720, where the TFTs 736a and 736b may be formed simultaneously. As shown in FIG. 7, TFT 736a is electrically connected to electrode segment 716a by via 740a, and TFT 736b is electrically connected to electrode segment 716b by via 740b. Each of the TFTs 736a and 736b can include a gate electrode 742 connected to a shared gate line, and each of the TFTs 736a and 736b can include a source/drain electrode 744 connected to a shared data line. In some implementations, a semiconductor layer can be disposed between the gate electrode 742 and the source/drain electrode 744. For example, the semiconductor layer can include a metal oxide semiconducting material, such as indium-gallium-zinc-oxide. The TFTs 736a and 736b may be configured to drive the movable electrode 714 to two or more positions across the gap 719 by a common voltage. With the shared gate line and the shared data line, a common voltage can be applied through the TFTs 736a and 736b instead of separate voltages. The stationary electrode 716 applies the common voltage to produce the electrostatic force, thereby driving the movable electrode 714 via electrostatic actuation to a position across the gap 719. Application of the common voltage from the electrode segments 716a and 716b via TFTs 736a and 736b that maintain constant charge can reduce the effects of tilt instability. In some implementations, the stationary electrode 716 may refer to a stationary layer or stationary structure including the electrode segments 716a and 716b as well as the TFTs 736a and 736b.

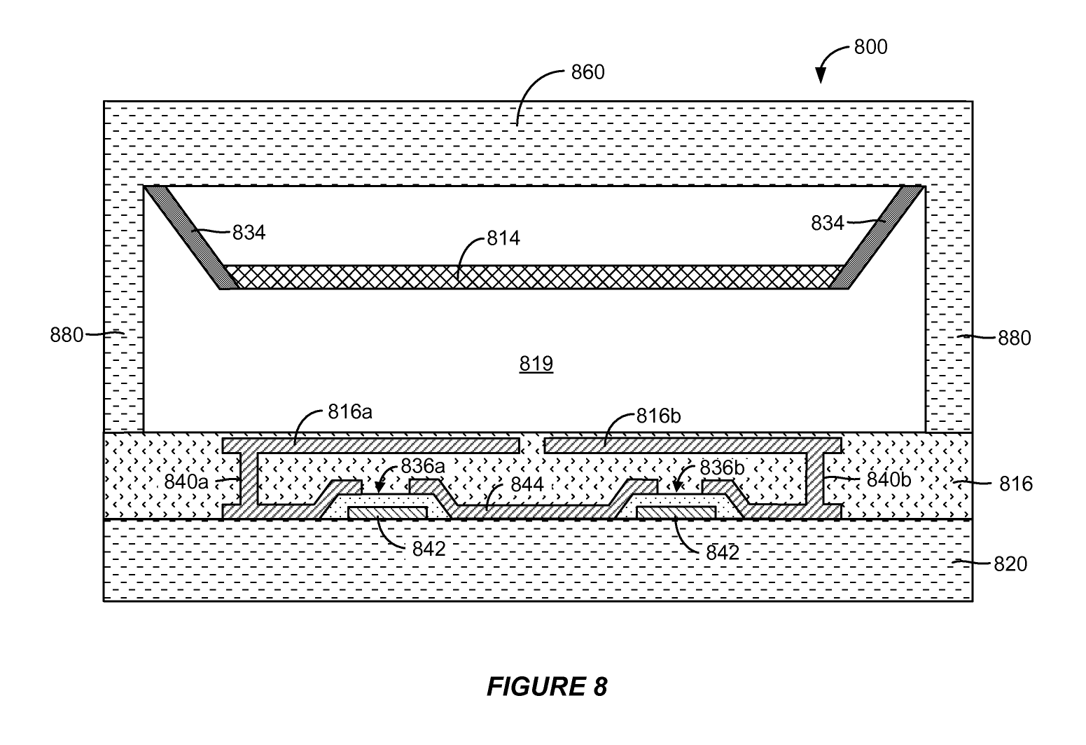

FIG. 8 shows a cross-sectional schematic diagram of an example EMS device with a segmented stationary electrode formed on a first substrate and an unsegmented movable electrode formed on a second substrate. An EMS device 800 can include a movable electrode 814 over a stationary electrode 816 and separated by a gap 819 therebetween. The stationary electrode 816 can be segmented into electrically isolated electrode segments 816a and 816b and formed on a first substrate 820. The movable electrode 814 can be unsegmented and formed on a second substrate 860 by connection via hinges 834. A plurality of hinges 834 can be connected to the movable electrode 814 to support the movable electrode 814 over the second substrate 860. In some implementations, the hinges 834 can be connected at the corners of the movable electrode 814 and symmetrically arranged about the center of the movable electrode 814. In some implementations, the EMS device 800 can be an IMOD, where the movable electrode 814 can include an absorber facing a viewing side and the stationary electrode 816 can include a mirror or mirror segments facing a rear side opposite the viewing side. For example, the absorber can include molychrome or other material configured to at least partially absorb light, and the mirror can include aluminum or other material configured to at least partially reflect light. In some implementations, the EMS device 800 can be a two-terminal EMS device.

Like the EMS device 700 in FIG. 7, the EMS device 800 in FIG. 8 includes a stationary electrode 816 having two or more electrically isolated electrode segments 816a and 816b, where the electrode segments 816a and 816b may be separated by a dielectric material. In some implementations, the electrode segments 816a and 816b can be symmetrical to each other. Furthermore, the EMS device 800 can include two or more TFTs 836a and 836b, where TFT 836a is electrically connected to electrode segment 816a by via 840a, and TFT 836b is electrically connected to electrode segment 816b by via 840b. Each of the TFTs 836a and 836b may be disposed over the substrate 820, where the TFTs 836a and 836b may be formed simultaneously. Each of the TFTs 836a and 836b can include a gate electrode 842 connected to a shared gate line, and each of the TFTs 836a and 836b can include a source/drain electrode 844 connected to a shared data line. In some implementations, a semiconductor layer can be disposed between the gate electrode 842 and the source/drain electrode 844. For example, the semiconductor layer can include a metal oxide semiconducting material, such as indium-gallium-zinc-oxide. The TFTs 836a and 836b can be configured to drive the movable electrode 814 to two or more positions across the gap 819 by a common voltage. In FIG. 8, the stationary electrode 816 applies the common voltage coming from either the gate line or the data line to produce electrostatic force for driving the movable electrode 814 towards the second substrate 860. Application of the common voltage from the electrode segments 816a and 816b via TFTs 836a and 836b that maintain constant charge can reduce the effects of tilt instability. In some implementations, the stationary electrode 816 may refer to a stationary layer or stationary structure including the electrode segments 816a and 816b as well as the TFTs 836a and 836b.

As illustrated in the example in FIG. 8, the EMS device 800 further includes spacers 880 between the first substrate 820 and the second substrate 860, where the spacers 880 can maintain a gap size for at least the gap 819. In some implementations, the EMS device 800 can permit separate manufacturing processes for the segmented stationary electrode 816 and the unsegmented movable electrode 814. For example, the segmented stationary electrode 816 can be formed on the first substrate 820 by a first process and the unsegmented movable electrode 814 can be formed on the second substrate 860 by a second process. In some implementations, the first substrate 820 can include a TFT substrate and the second substrate 860 can include a MEMS substrate. The TFT substrate can include one or more layers configured for manufacturing TFTs 836a and 836b as well as electrode segments 816a and 816b over the TFT substrate, and the MEMS substrate can include one or more layers configured for manufacturing the movable electrode 814 over the MEMS substrate. In some implementations, spacers 880 may be provided on the second substrate 860 so that the stationary electrode 816 can be provided on the spacers 880 to define the gap 819.

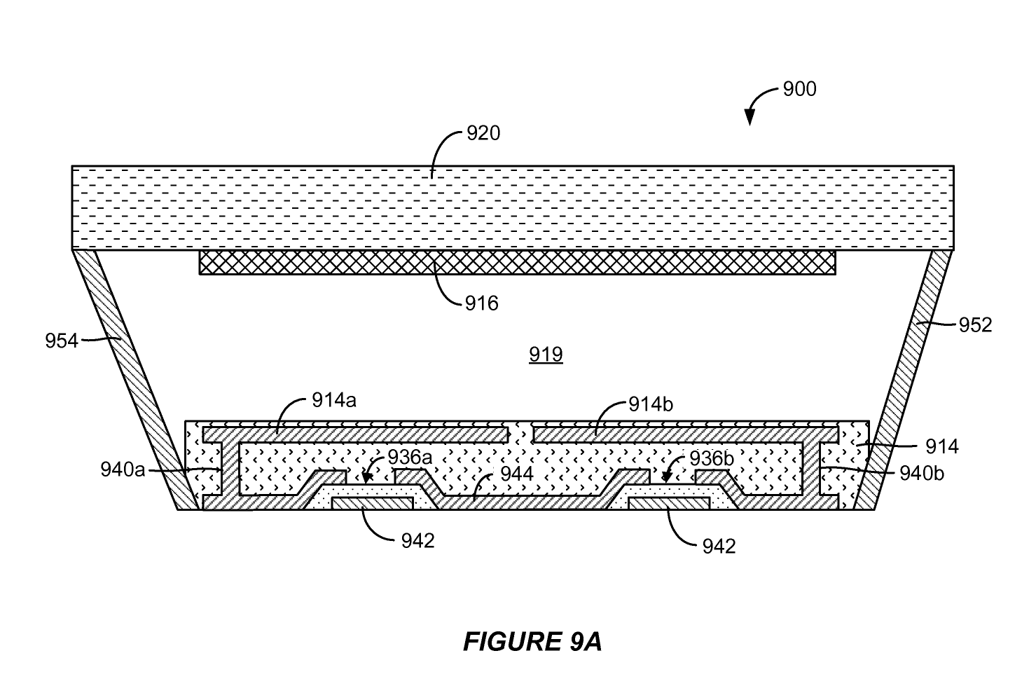

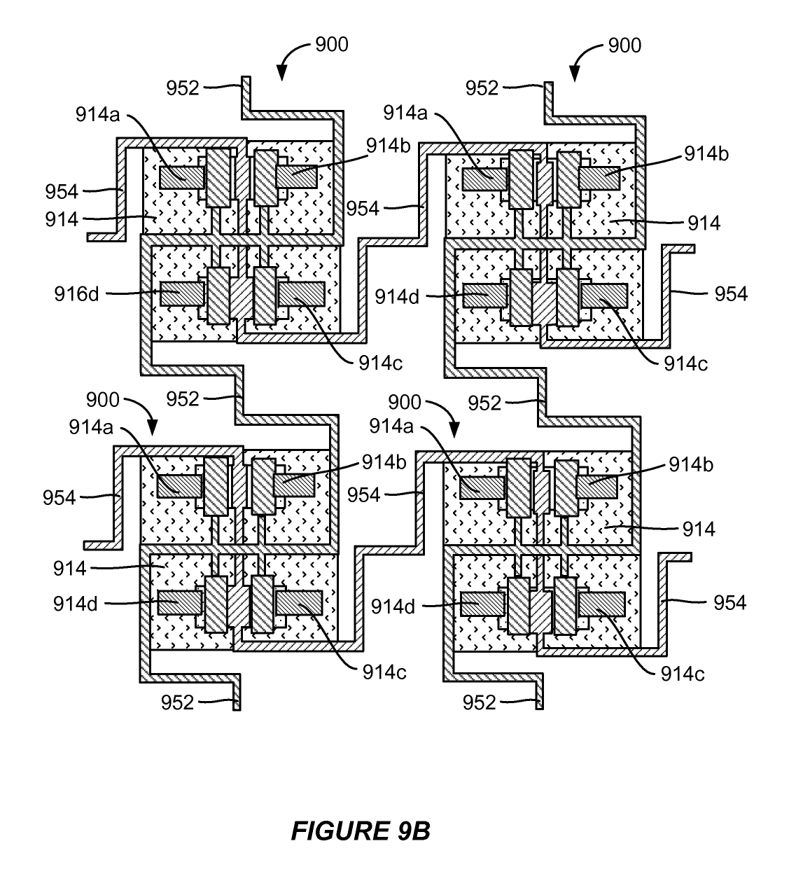

FIG. 9A shows a cross-sectional schematic side view of an example EMS device with a movable electrode having two or more electrically isolated electrode segments each connected to a TFT. An EMS device 900 includes a movable electrode 914 over a stationary electrode 916 and separated by a gap 919 therebetween. The movable electrode 914 can be segmented into electrically isolated electrode segments 914a and 914b. In some implementations, the electrode segments 914a and 914b can be symmetrical to each other. Even though the movable electrode 914 includes electrode segments 914a and 914b, the movable electrode 914 is configured to move as a single unit. In other words, the electrode segments 914a and 914b do not move independently of one another. The stationary electrode 916 can be unsegmented and formed on a substrate 920. The EMS device 900 can include a plurality of hinges 952 and 954 that connect to the movable electrode 914 to support the movable electrode 914 over the substrate 920. In some implementations, the hinges 952 and 954 can be connected at the corners of the movable electrode 914 and symmetrically arranged about the center of the movable electrode 914. In some implementations, the EMS device 900 can be an IMOD, where the stationary electrode 916 can include an absorber facing a viewing side and the movable electrode 914 can include a mirror or mirror segments facing a rear side opposite the viewing side. For example, the absorber can include molychrome or other material configured to at least partially absorb light, and the mirror can include aluminum or other material configured to at least partially reflect light. In some implementations, the EMS device 900 can be a two-terminal EMS device without a top plate.

The EMS device 900 includes a movable electrode 914 having two or more electrically isolated electrode segments 914a and 914b, where the electrode segments 914a and 914b may be separated by dielectric material. The EMS device 900 can further include two or more TFTs 936a and 936b, where TFT 936a is electrically connected to electrode segment 914a by via 940a, and TFT 936b is electrically connected to electrode segment 914b by via 940b. Each of the TFTs 936a and 936b may be formed over the electrode segments 914a and 914b, where the TFTs 936a and 936b may be formed simultaneously. Each of the TFTs 936a and 936b can include a gate electrode 942 connected to a shared gate line, and each of the TFTs 936a and 936b can include a source/drain electrode 944 connected to a shared data line. In some implementations, a semiconductor layer can be disposed between the gate electrode 942 and the source/drain electrode 944. For example, the semiconductor layer can include a metal oxide semiconducting material, such as indium-gallium-zinc-oxide. The TFTs 936a and 936b can be configured to drive the movable electrode 914 to two or more positions across the gap 919 by a common voltage. The common voltage can be applied from either a gate line or a data line providing a signal to the TFTs 936a and 936b, where the common voltage produces an electrostatic force for driving the movable electrode 914 towards the stationary electrode 916. Application of the common voltage from the electrode segments 914a and 914b via TFTs 936a and 936b that maintain constant charge can reduce the effects of tilt instability. In some implementations, the movable electrode 914 may refer to a movable layer or movable structure including the electrode segments 914a and 914b as well as the TFTs 936a and 936b.

In some implementations, the EMS device 900 can further include a first hinge 952 and a second hinge 954 for supporting the movable electrode 914. In FIG. 9, the first hinge 952 can include the gate line that is electrically connected to the gate electrode 942, and the second hinge 954 can include the data line that is electrically connected to the source/drain electrode 944. Accordingly, the gate line and the data line can be routed through the hinges 952 and 954.

FIG. 9B shows a cross-sectional schematic top view of a plurality of example EMS devices from FIG. 9A with shared gate and data lines. The plurality of EMS devices 900 may be arranged in an array, such as an array of pixels in a display. Each of the EMS devices 900 in the array can include a movable electrode 914 having four electrically isolated electrode segments 914a, 914b, 914c, and 914d. In some implementations, each of the electrode segments 914a, 914b, 914c, and 914d can be identical or at least substantially identical in composition and dimension.

As illustrated in FIG. 9B, each movable electrode 914 can be a square plate. First hinges 952 and second hinges 954 can support the movable electrode 914 in the EMS device 900 by connecting at the corners of the square plate. For example, the first hinges 952 can connect at the upper right and bottom left of each movable electrode 914, and the second hinges 954 can connect at the upper left and bottom right of each movable electrode 914. For each EMS device 900, the first hinges 952 can include the gate line so that the gate line connects to each of a plurality of gate electrodes in the movable electrode 914, thereby allowing the gate line to be shared by the electrode segments 914a, 914b, 914c, and 914d in the EMS device 900. The gate line can connect from one EMS device to another EMS device in the array by columns, meaning that an EMS device above is connected to an adjacent EMS device below by the gate line. In some implementations, the gate line can form column electrodes in the array. Moreover, for each EMS device 900, the second hinges 954 can include the data line so that the data line connects to each of a plurality of source/drain electrodes in the movable electrode 914, thereby allowing the data line to be shared by the electrode segments 914a, 914b, 914c, and 914d in the EMS device 900. The data line can connect from one EMS device to another EMS device in the array by rows, meaning that an EMS device on the left-hand side is connected to an adjacent EMS device on the right-hand side by the data line. In some implementations, the data line can form row electrodes in the array.

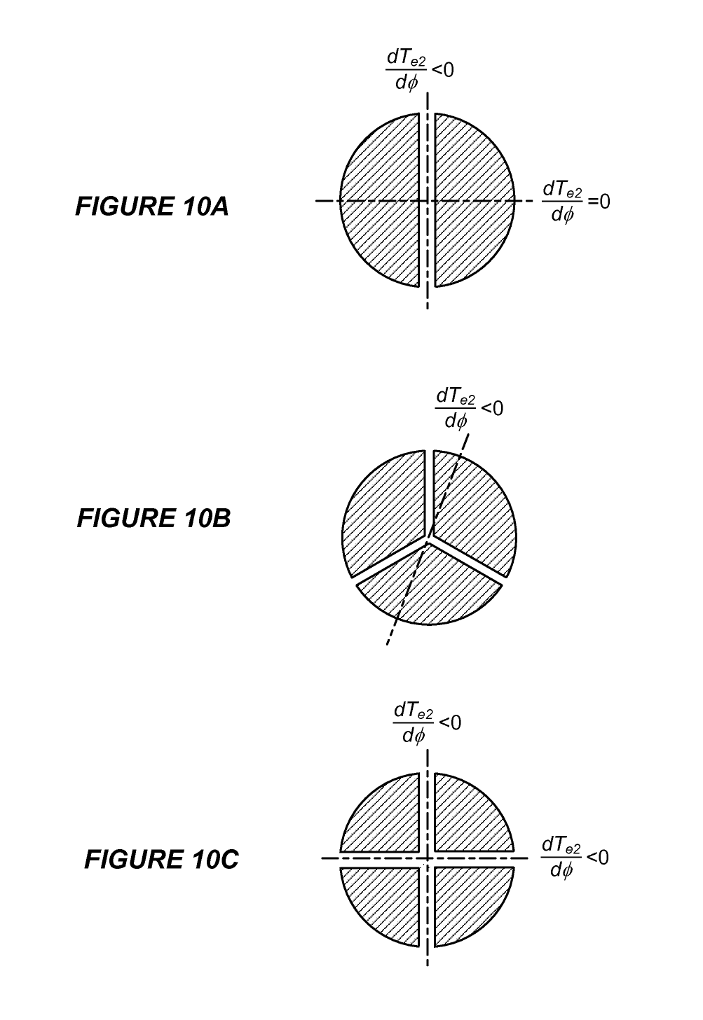

It will be understood that the segmented movable electrode or segmented stationary electrode described above is not limited to a number of segments, but can include any suitable number of segments. Also, the segmented movable electrode or segmented stationary electrode can include any suitable shape, such as square, rectangular, circular, etc. FIGS. 10A, 10B, and 10C show example circular electrodes cut into halves, thirds, and fourths, respectively. FIG. 10A shows a schematic diagram of an example electrode separated into halves. When the electrode is divided into two equal segments, a negative feedback term is obtained for increased stability to a movable electrode along one rotation axis. However, there is no negative feedback term for increased stability along any other rotation axis. FIG. 10B shows a schematic diagram of an example electrode separated into thirds. When the electrode is divided into three equal segments, a negative feedback term is obtained for increased stability to a movable electrode along any rotation axis. However, the increase in stability may be smaller compared to the segmented electrode in FIG. 10A and FIG. 10C, because there is at least a third of an area in each of the three equal segments that do not contribute to stability. FIG. 10C shows a schematic diagram of an example electrode separated into fourths. When the electrode is divided into four equal segments, a negative feedback term is obtained for increased stability to a movable electrode along any rotation axis.

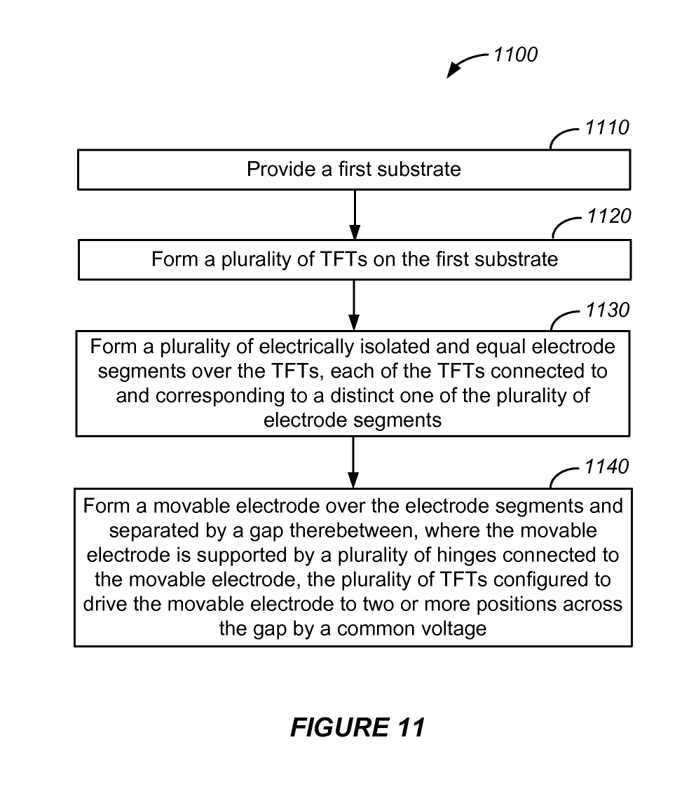

FIG. 11 shows a flow diagram illustrating an example process for manufacturing an EMS device. The process 1100 may be performed in a different order or with different, fewer or additional operations.

At block 1110, a first substrate is provided. In some implementations, the first substrate can include any suitable substrate material, such as a semiconducting material, glass, or plastic as discussed earlier herein.

At block 1120, a plurality of TFTs is formed on the first substrate. The number of TFTs formed on the first substrate may correspond to the number of electrode segments to be subsequently formed in the EMS device. Each of the TFTs may be formed simultaneously, where each of the layers of the TFTs may be deposited and patterned at the same time. In some implementations, for example, forming a TFT may include forming a gate electrode, forming a semiconductor layer over the gate electrode, and forming a source/drain electrode over the semiconductor layer. However, it will be understood that the TFT may have other TFT designs, including top gate and bottom gate TFTs, planar and staggered TFTs, etc. In some implementations, a gate line for the EMS device may connect to the gate electrode, and a data line for the EMS device may connect to the source/drain electrode. In some implementations, a first dielectric layer may be deposited over the plurality of TFTs.

At block 1130, a plurality of electrically isolated electrode segments are formed over the TFTs, each of the TFTs connected to and corresponding to a distinct one of the plurality of electrode segments. The first dielectric layer may be formed between the plurality of TFTs and the plurality of electrode segments. In some implementations, forming the electrode segments can include depositing an electrically conductive layer over the first dielectric layer and over the plurality of TFTs, and patterning the electrically conductive layer into electrode segments. In some implementations, the electrode segments can be symmetrical to one another. The electrically conductive layer can include a reflective metallic material, such as aluminum or aluminum alloy. In some implementations, a second dielectric layer may be deposited over the electrode segments and between the segments to electrically isolate the electrode segments. In some implementations, the plurality of electrically isolated electrode segments include four or more electrically isolated electrode segments. In some implementations, a plurality of vias can be formed extending through the first dielectric layer to connect the plurality of TFTs to the plurality of electrode segments.

At block 1140, a movable electrode is formed over the electrode segments and separated by a gap therebetween, where the movable electrode is supported by a plurality of hinges connected to the movable electrode, the plurality of TFTs configured to drive the movable electrode to two or more positions across the gap by a common voltage. The common voltage may be associated with signals provided by the gate line or the data line. After the TFTs apply the common voltage, the TFTs may provide isolation between the movable electrode and the electrode segments during actuation. That way, voltages may vary for each electrode segment depending on its gap size between the electrode segment and the movable electrode. The plurality of TFTs can be configured to maintain a fixed charge in each of the electrode segments when the movable electrode is driven across the gap. In some implementations, the movable electrode can include an absorber and the electrode segments can include a mirror or mirror segments. The hinges may be symmetrically arranged about the center of the movable electrode. In some implementations, the plurality of hinges may be formed on the second dielectric layer over the first substrate.

In some implementations, a second substrate may be provided opposite the first substrate, where the plurality of hinges are formed on the second substrate for supporting the movable electrode. The second substrate may include any substantially transparent material, such as glass. Glass substrates (sometimes referred to as glass plates or panels) may be or include a borosilicate glass, a soda lime glass, photoglass, quartz, Pyrex or other suitable glass material. Where the EMS device is a display device, an image for a display can be provided through the second substrate. In some implementations, spacers may be provided between the first substrate and the second substrate to define a maximum height of the gap between the movable electrode and the electrode segments. Thus, the TFTs may be formed on the first substrate while the movable electrode and hinges may be separately formed on the second substrate.

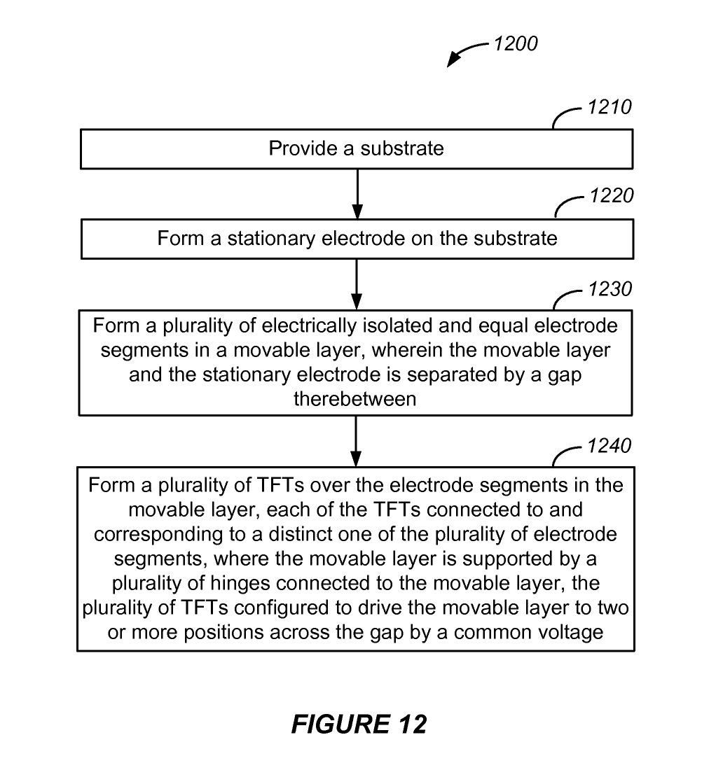

FIG. 12 shows a flow diagram illustrating another example process for manufacturing an EMS device. The process 1200 may be performed in a different order or with different, fewer or additional operations.

At block 1210, a substrate is provided. The first substrate can include any suitable substrate material, such as a semiconducting material, glass, or plastic. In some implementations, the substrate may include any substantially transparent material. Where the device is a display device, an image for a display can be provided through the substrate.

At block 1220, a stationary electrode is formed over the substrate. In some implementations, the stationary electrode includes an absorber. For example, the absorber can include molychrome or other suitable material configured to at least partially absorb light. In some implementations, a plurality of hinges are formed on the substrate for supporting a movable layer over the stationary electrode, where at least one of the hinges include a gate line and where at least one of the hinges include a data line.

At block 1230, a plurality of electrically isolated electrode segments are formed in the movable layer, where the movable layer and the stationary electrode are separated by a gap therebetween. A movable layer can be formed over the stationary electrode. In some implementations, the movable layer can be formed on a sacrificial layer between the stationary electrode and the movable layer, where subsequent removal of the sacrificial layer can release the EMS device. To form the movable layer, an electrically conductive layer can be deposited over the sacrificial layer and patterned into the electrode segments. In some implementations, the electrode segments can be symmetrical to one another. In some implementations, the plurality of electrode segments can include four or more electrode segments. In some implementations, a dielectric layer can be formed over the electrode segments and between the electrode segments, where the dielectric layer electrically isolates the electrode segments from one another.

At block 1240, a plurality of TFTs are formed over the electrode segments in the movable layer, each of the TFTs connected to and corresponding to a distinct one of the plurality of electrode segments, where the movable layer is supported by a plurality of hinges connected to the movable layer, the plurality of TFTs configured to drive the movable layer to two or more positions across the gap by a common voltage. After the TFTs apply the common voltage, the TFTs may provide isolation between the movable layer and the stationary electrode during actuation. That way, voltages may vary for each electrode segment depending on its gap size between the electrode segment and the stationary electrode. The plurality of TFTs can be configured to maintain a fixed charge in each of the electrode segments when the movable layer is driven across the gap. In forming the dielectric layer over the electrode segments, the dielectric layer may be formed between the TFTs and the electrode segments. In some implementations, a plurality of vias are formed extending through the dielectric layer to connect the plurality of TFTs to the plurality of electrode segments.

Each of the TFTs may be formed simultaneously, where each of the layers of the TFTs may be deposited and patterned at the same time. The number of TFTs formed on the dielectric layer may correspond to the number of electrode segments. In some implementations, for example, forming a TFT may include forming a source/drain electrode, forming a semiconductor layer over the source/drain electrode, and forming a gate electrode over the semiconductor layer. However, it will be understood that the TFT may have other TFT architectures, including top gate and bottom gate TFTs, planar and staggered TFTs, etc. In some implementations, at least one of the hinges including the gate line may connect to the gate electrode, and at least one of the hinges including the data line may connect to the source/drain electrode.

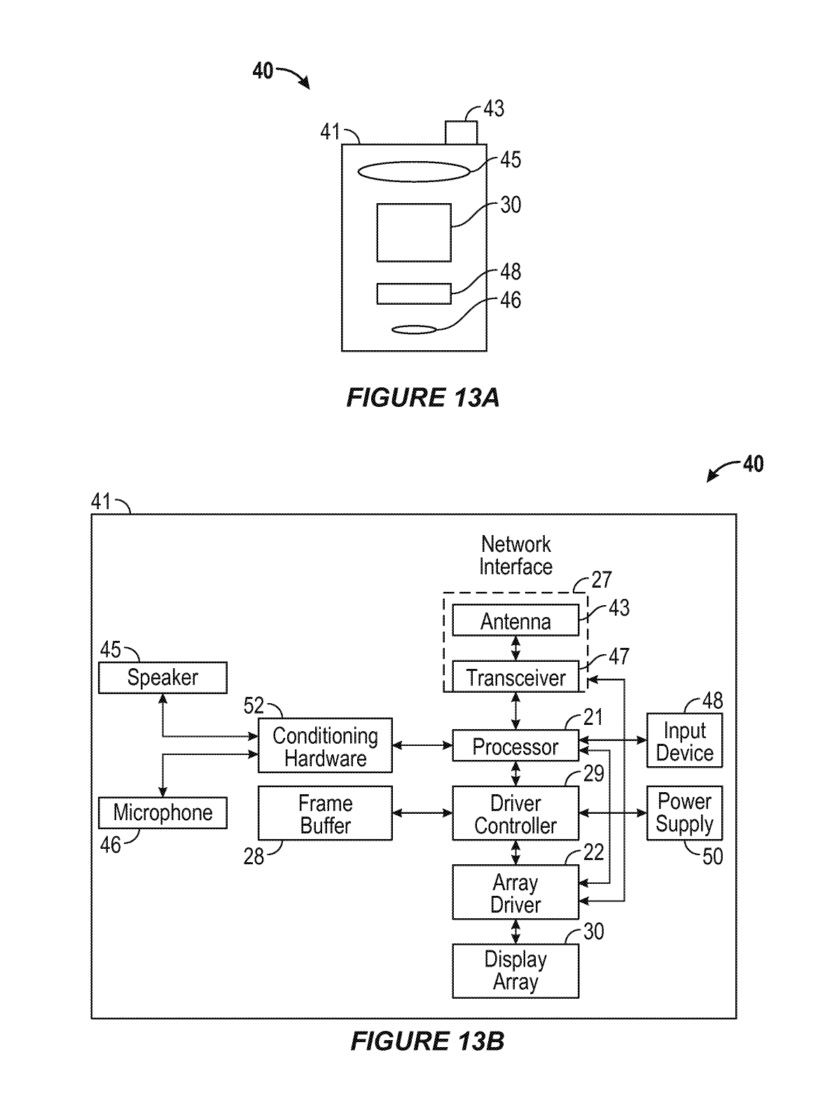

FIGS. 13A and 13B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 13A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 13A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An electromechanical systems (EMS) device comprising:
a substrate;
a stationary electrode over the substrate;
a movable electrode over the stationary electrode with a gap between the movable electrode and the stationary electrode, wherein at least one of the stationary electrode and the movable electrode includes a plurality of electrically isolated electrode segments; and
a plurality of thin film transistors (TFTs), each of the TFTs connected to and corresponding to a distinct one of the plurality of electrode segments, the plurality of TFTs configured to drive the movable electrode to two or more positions across the gap by a common voltage.

2. The device of claim 1, wherein the plurality of electrically isolated electrode segments include four or more electrically isolated electrode segments.

3. The device of claim 1, wherein the plurality of TFTs are configured to maintain a fixed charge in the plurality of electrically isolated electrode segments when the movable electrode is driven across the gap.

4. The device of claim 1, further comprising:
a plurality of hinges connected to the movable electrode, wherein the hinges are symmetrically arranged about the center of the movable electrode.

5. The device of claim 4, wherein the hinges are connected to the movable electrode at corners of the movable electrode.

6. The device of claim 1, further comprising:
a gate line electrically coupled to the plurality of TFTs, wherein each of the plurality of TFTs share the gate line; and
a data line electrically coupled to the plurality of TFTs, wherein each of the plurality of TFTs share the data line.

7. The device of claim 6, wherein the gate line or the data line is configured to provide a signal associated with the common voltage.

8. The device of claim 6, wherein each of the TFTs comprises:
a gate electrode, wherein the gate electrode configured to receive a first signal from the gate line associated with the common voltage; and
a source/drain electrode, the source/drain electrode configured to receive a second signal from the data line associated with the common voltage.

9. The device of claim 6, further comprising:
a plurality of hinges connected to the movable electrode, wherein at least one of the hinges includes the gate line and at least one of the hinges includes the data line.

10. The device of claim 1, wherein the movable electrode includes a mirror layer and the stationary electrode includes an absorber.

11. The device of claim 1, wherein the movable electrode includes an absorber and the stationary electrode includes a mirror.

12. The device of claim 1, wherein the movable electrode is movable over a range of stable positions in which application of the common voltage by the plurality of TFTs moves the movable electrode to a position within the range of stable positions.

13. The device of claim 12, wherein the range of stable positions includes a range of positions that is equal to or greater than 75% of a maximum height of the gap.

14. The device of claim 1, further comprising:
a processor that is configured to communicate with at least one of the movable electrode and the stationary electrode, the processor being configured to process image data; and
a memory device that is configured to communicate with the processor.

15. The device of claim 14, further comprising:
a driver circuit configured to send at least one signal to at least one of the movable electrode and the stationary electrode;
a controller configured to send at least a portion of the image data to the driver circuit; and
an image source module configured to send the image data to the processor, wherein the image source module includes one or more components selected from the group consisting of a receiver, a transceiver, and a transmitter.

16. An electromechanical systems (EMS) device comprising:
a substrate;
a stationary electrode over the substrate;
a movable electrode over the stationary electrode with a gap between the movable electrode and the stationary electrode, wherein at least one of the stationary electrode and the movable electrode includes means for electrically isolating into electrode segments; and
means for maintaining a fixed charge in the electrically isolating means when the movable electrode is driven across the gap, the means for maintaining the fixed charge connected to the electrically isolating means and configured to drive the movable electrode across the gap by a common voltage.

17. The device of claim 16, wherein the maintaining the fixed charge means includes a plurality of thin film transistors (TFTs), each of the plurality of TFTs connected to and corresponding to a distinct one of the electrode segments.

18. The device of claim 17, further comprising:
a gate line electrically coupled to the plurality of TFTs, wherein each of the plurality of TFTs share the gate line; and
a data line electrically coupled to the plurality of TFTs, wherein each of the plurality of TFTs share the data line.

19. The device of claim 16, wherein the electrically isolating means includes four or more electrically isolated electrode segments each separated by dielectric material.

20. The device of claim 16, further comprising:
a plurality of hinges connected to the movable electrode, wherein the hinges are symmetrically arranged about the center of the movable electrode.

21. A method of manufacturing an electromechanical systems (EMS) device, the method comprising:
providing a first substrate;
forming a plurality of thin film transistors (TFTs) on the first substrate;
forming a plurality of electrically isolated electrode segments over the TFTs, each of the TFTs connected to and corresponding to a distinct one of the plurality of electrode segments; and
forming a movable electrode over the electrode segments and separated by a gap therebetween, wherein the movable electrode is supported by a plurality of hinges connected to the movable electrode, the plurality of TFTs configured to drive the movable electrode to two or more positions across the gap by a common voltage.

22. The method of claim 21, further comprising:
forming a dielectric layer between the TFTs and the electrode segments, the dielectric layer electrically isolating the electrode segments from one another; and
forming a plurality of vias extending through the dielectric layer to connect the plurality of TFTs to the plurality of electrode segments.

23. The method of claim 21, wherein the plurality of electrically isolated electrode segments include four or more electrically isolated electrode segments.

24. The method of claim 21, further comprising:
providing a second substrate opposite the first substrate, wherein the plurality of hinges are formed on the second substrate for supporting the movable electrode.

25. A method of manufacturing an electromechanical systems (EMS) device, the method comprising:
providing a substrate;
forming a stationary electrode on the substrate;
forming a plurality of electrically isolated electrode segments in a movable layer, wherein the movable layer and the stationary electrode is separated by a gap therebetween; and
forming a plurality of TFTs over the electrode segments in the movable layer, each of the TFTs connected to and corresponding to a distinct one of the plurality of electrode segments, wherein the movable layer is supported by a plurality of hinges connected to the movable layer, the plurality of TFTs configured to drive the movable layer to two or more positions across the gap by a common voltage.

26. The method of claim 25, further comprising:
forming the plurality of hinges on the substrate for supporting the movable layer, wherein at least one of the hinges includes a gate line and wherein at least one of the hinges includes a data line.

27. The method of claim 25, further comprising:
forming a dielectric layer between the TFTs and the electrode segments, the dielectric layer electrically isolating the electrode segments from one another; and
forming a plurality of vias extending through the dielectric layer to connect the plurality of TFTs to the plurality of electrode segments.
